(19) United States
(12) Patent Application Publication
(10) Pub. No.: US 2025/0038139 A1
(43) Pub. Date: Jan. 30, 2025

(54) ADHESIVE ATTACHMENT OF PLASMA-ETCH-DICED RFID INTEGRATED CIRCUITS WITH STRUCTURAL SUPPORT

(71) Applicant: Impinj, Inc., Seattle, WA (US)

(72) Inventors: James GUZZO; Harley K. HEINRICH, Seattle, WA (US); Christopher J. DIORIO, Shoreline, WA (US)

(73) Assignee: Impinj, Inc., Seattle, WA (US)

(21) Appl. No.: 18/713,755

(22) PCT Filed: Dec. 2, 2022
(86) PCT No.: PCT/US22/51694

§ 371 Date: May 28, 2024

Related U.S. Application Data
(60) Provisional application No. 63/285,518, filed on Dec. 3, 2021.

(51) Int. Cl. H01L 23/00; G06K 19/077

(52) U.S. Cl. CPC H01L 24/05; G06K 19/07722; H01L 24/03; H01L 2224/0391; H01L 2224/04026; H01L 2224/05073; H01L 2224/05552; H01L 2224/05561; H01L 2224/05573

(57) ABSTRACT

Plasma etching, when used to dice RFID ICs, may deposit fluoropolymer on IC surfaces, which may prevent IC adhesion to tag substrates or inlays. To address this issue, an RFID IC can include specific surface areas from which fluoropolymer can be relatively easily removed and therefore are suitable for subsequent adhesive attachment. These surface areas may include oxide or nitride surfaces, from which fluoropolymer can be relatively easily removed, and may exclude metal or organic repassivation layers, which cannot be easily cleaned of fluoropolymer. The RFID IC may also include a support structure disposed on an insulating layer and between contact pads to mitigate a deformation of an inlay during mounting of the IC to the inlay. Portions of the insulating layer may be exposed between contact pads to adhere to an adhesive for bonding the IC to the inlay.

### CROSS REFERENCE TO RELATED APPLICATIONS

This patent application claims the benefit of U.S. Provisional Patent Application Ser. No. 63/285,518 filed on Dec. 3, 2021. The disclosures of the above application are hereby incorporated by reference for all purposes.

### BACKGROUND

Radio-Frequency Identification (RFID) systems typically include RFID readers, also known as RFID reader/writers or RFID interrogators, and RFID tags. RFID systems can be used in many ways for locating and identifying objects to which the tags are attached. RFID systems are useful in product-related and service-related industries for tracking objects being processed, inventoried, or handled. In such cases, an RFID tag is usually attached to an individual item, or to its package. The RFID tag typically includes, or is, a radio-frequency (RF) integrated circuit (IC).

In principle, RFID techniques entail using an RFID reader to inventory one or more RFID tags, where inventorying involves singulating a tag, receiving an identifier from a tag, and/or acknowledging a received identifier (e.g., by transmitting an acknowledge command). “Singulated” is defined as a reader singling-out one tag, potentially from among multiple tags, for a reader-tag dialog. “Identifier” is defined as a number identifying the tag or the item to which the tag is attached, such as a tag identifier (TID), electronic product code (EPC), etc. An “inventory round” is defined as a reader staging RFID tags for successive inventorying. The reader transmitting an RF wave performs the inventory. The RF wave is typically electromagnetic, at least in the far field. The RF wave can also be predominantly electric or magnetic in the near or transitional near field. The RF wave may encode one or more commands that instruct the tags to perform one or more actions. The operation of an RFID reader sending commands to an RFID tag is sometimes known as the reader “interrogating” the tag.

In typical RFID systems, an RFID reader transmits a modulated RF inventory signal (a command), receives a tag reply, and transmits an RF acknowledgement signal responsive to the tag reply. A tag that replies to the interrogating RF wave does so by transmitting back another RF wave. The tag either generates the transmitted back RF wave originally, or by reflecting back a portion of the interrogating RF wave in a process known as backscatter. Backscatter may take place in a number of ways.

The reflected-back RF wave may encode data stored in the tag, such as a number. The response is demodulated and decoded by the reader, which thereby identifies, counts, or otherwise interacts with the associated item. The decoded data can denote a serial number, a price, a date, a time, a destination, an encrypted message, an electronic signature, other attribute(s), any combination of attributes, and so on. Accordingly, when a reader receives tag data it can learn about the item that hosts the tag and/or about the tag itself.

An RFID tag typically includes an antenna section, a radio section, a power-management section, and frequently a logical section, a memory, or both. In some RFID tags the power-management section includes an energy storage device such as a battery. RFID tags with an energy storage device are known as battery-assisted, semi-active, or active tags. Other RFID tags can be powered solely by the RF signal they receive. Such RFID tags do not include an energy storage device and are called passive tags. Of course, even passive tags typically include temporary energy- and data/flag-storage elements such as capacitors or inductors.

### BRIEF SUMMARY

This summary is provided to introduce a selection of concepts in a simplified form that are further described below in the Detailed Description. This summary is not intended to identify key features or essential features of the claimed subject matter, nor is it intended as an aid in determining the scope of the claimed subject matter.

Plasma etching, when used to dice RFID ICs, may deposit fluoropolymer on IC surfaces, which may prevent IC adhesion to tag substrates or inlays. To address this issue, an RFID IC can include specific surface areas from which fluoropolymer can be relatively easily removed and therefore are suitable for subsequent adhesive attachment. These surface areas may include oxide or nitride surfaces, from which fluoropolymer can be relatively easily removed, and may exclude metal or organic repassivation layers, which cannot be easily cleaned of fluoropolymer.

According to some examples, an RFID IC may include a semiconductor substrate with circuitry and an insulating layer thereon. The insulating layer may include openings uncovering IC contacts on the substrate and electrically coupled to the circuitry. The RFID IC may further include a repassivation layer on the insulating layer and contact pads on the repassivation layer electrically coupled to respective IC contacts. The RFID IC may also include a support structure disposed on the insulating layer and between the contact pads to mitigate a deformation of an inlay during mounting of the IC to the inlay. Two portions of the insulating layer may be exposed between the contact pads to adhere to an adhesive for bonding the IC to the inlay, and the support structure may be disposed between the first and second portions of the insulating layer.

These and other features and advantages will be apparent from a reading of the following detailed description and a review of the associated drawings. It is to be understood that both the foregoing general description and the following detailed description are explanatory only and are not restrictive of aspects as claimed.

### BRIEF DESCRIPTION OF THE DRAWINGS

The following Detailed Description proceeds with reference to the accompanying drawings, in which:

FIG. 1 is a block diagram of components of an RFID system.

FIG. 2 is a diagram showing components of a passive RFID tag, such as a tag that can be used in the system of FIG. 1.

FIG. 3 is a conceptual diagram for explaining a half-duplex mode of communication between the components of the RFID system of FIG. 1.

FIG. 4 is a block diagram showing a detail of an RFID tag, such as the one shown in FIG. 2.

FIGS. 5A and 5B illustrate signal paths during tag-to-reader and reader-to-tag communications in the block diagram of FIG. 4.

FIG. 6 depicts an IC with large contact pads.

FIG. 7 depicts an IC having large contact pads with cutouts, according to examples.

FIG. 8A through 8D illustrate various layers of an RFID IC with a support structure.

FIG. 9 illustrates a see-through top view of an RFID IC with a support structure.

### DETAILED DESCRIPTION

In the following detailed description, references are made to the accompanying drawings that form a part hereof, and in which are shown by way of illustration specific embodiments or examples. These embodiments or examples may be combined, other aspects may be utilized, and structural changes may be made without departing from the spirit or scope of the present disclosure. The following detailed description is therefore not to be taken in a limiting sense, and the scope of the present invention is defined by the appended claims and their equivalents.

As used herein, “memory” is one of ROM, RAM, SRAM, DRAM, NVM, EEPROM, FLASH, Fuse, MRAM, FRAM, and other similar volatile and nonvolatile information-storage technologies. Some portions of memory may be writeable and some not. “Instruction” refers to a request to a tag to perform a single explicit action (e.g., write data into memory). “Command” refers to a reader request for one or more tags to perform one or more actions, and includes one or more tag instructions preceded by a command identifier or command code that identifies the command and/or the tag instructions. “Program” refers to a request to a tag to perform a set or sequence of instructions (e.g., read a value from memory and, if the read value is less than a threshold then lock a memory word). “Protocol” refers to an industry standard for communications between a reader and a tag (and vice versa), such as the Class-1 Generation-2 UHF RFID Protocol for Communications at 860 MHz-960 MHz by GS1 EPCglobal, Inc. (“Gen2 Protocol”), versions 1.2.0 and 2.0 of which are hereby incorporated by reference.

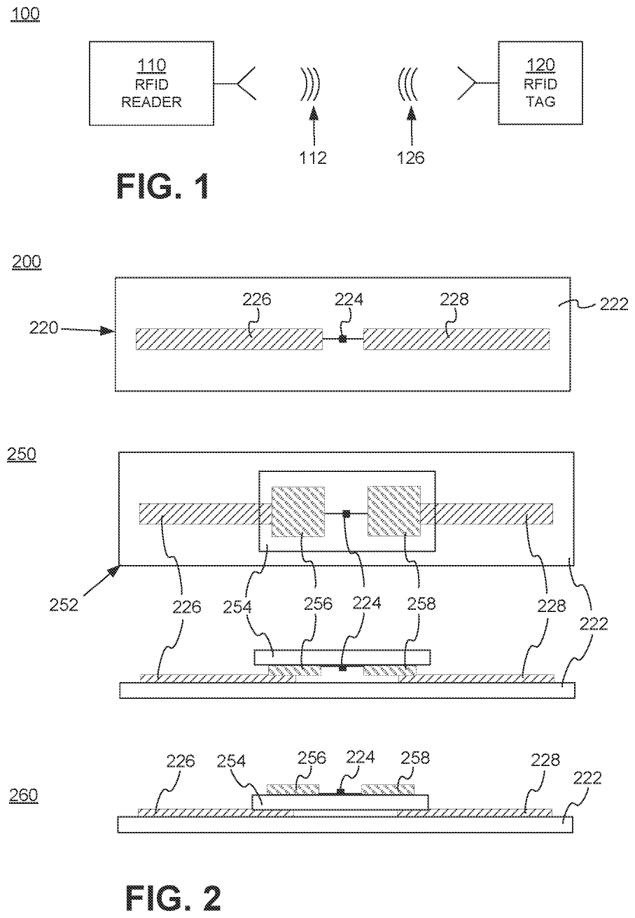

FIG. 1 is a diagram of the components of a typical RFID system 100, incorporating examples. An RFID reader 110 and a nearby RFID tag 120 communicate via RF signals 112 and 126. When sending data to tag 120, reader 110 may generate RF signal 112 by encoding the data, modulating an RF waveform with the encoded data, and transmitting the modulated RF waveform as RF signal 112. In turn, tag 120 may receive RF signal 112, demodulate encoded data from RF signal 112, and decode the encoded data. Similarly, when sending data to reader 110 tag 120 may generate RF signal 126 by encoding the data, modulating an RF waveform with the encoded data, and causing the modulated RF waveform to be sent as RF signal 126. The data sent between reader 110 and tag 120 may be represented by symbols, also known as RFID symbols. A symbol may be a delimiter, a calibration value, or implemented to represent binary data, such as “0” and “1”, if desired. Upon processing by reader 110 and tag 120, symbols may be treated as values, numbers, or any other suitable data representations.

The RF waveforms transmitted by reader 110 and/or tag 120 may be in a suitable range of frequencies, such as those near 900 MHZ, 13.56 MHZ, or similar. In some examples, RF signals 112 and/or 126 may include non-propagating RF signals, such as reactive near-field signals or similar. RFID tag 120 may be active or battery-assisted (i.e., possessing its own power source), or passive. In the latter case, RFID tag 120 may harvest power from RF signal 112.

FIG. 2 is a diagram of an RFID tag 220, which may function as tag 120 of FIG. 1. Tag 220 may be formed on a substantially planar inlay 222, which can be made in any suitable way. Tag 220 includes a circuit which may be implemented as an IC 224. In some examples, IC 224 is fabricated in complementary metal-oxide semiconductor (CMOS) technology. In other examples, IC 224 may be fabricated in other technologies such as bipolar junction transistor (BJT) technology, metal-semiconductor field-effect transistor (MESFET) technology, and others as will be well known to those skilled in the art. IC 224 is arranged on inlay 222.

Tag 220 also includes an antenna for transmitting and/or interacting with RF signals. In some examples, the antenna can be etched, deposited, and/or printed metal on inlay 222; conductive thread formed with or without substrate 222; nonmetallic conductive (such as graphene) patterning on substrate 222; a first antenna coupled inductively, capacitively, or galvanically to a second antenna; or can be fabricated in myriad other ways that exist for forming antennas to receive RF waves. In some examples, the antenna may even be formed in IC 224. Regardless of the antenna type, IC 224 is electrically coupled to the antenna via suitable IC contacts (not shown in FIG. 2). The term “electrically coupled” as used herein may mean a direct electrical connection, or it may mean a connection that includes one or more intervening circuit blocks, elements, or devices. The “electrical” part of the term “electrically coupled” as used in this document shall mean a coupling that is one or more of ohmic/galvanic, capacitive, and/or inductive. Similarly, the terms “electrically isolated” or “electrically decoupled” as used herein mean that electrical coupling of one or more types (e.g., galvanic, capacitive, and/or inductive) is not present, at least to the extent possible. For example, elements that are electrically isolated from each other are galvanically isolated from each other, capacitively isolated from each other, and/or inductively isolated from each other. Of course, electrically isolated components will generally have some unavoidable stray capacitive or inductive coupling between them, but the intent of the isolation is to minimize this stray coupling when compared with an electrically coupled path.

IC 224 is shown with a single antenna port, comprising two IC contacts electrically coupled to two antenna segments 226 and 228 which are shown here forming a dipole. Many other examples are possible using any number of ports, contacts, antennas, and/or antenna segments. Antenna segments 226 and 228 are depicted as separate from IC 224, but in other examples the antenna segments may alternatively be formed on IC 224. Tag antennas according to examples may be designed in any form and are not limited to dipoles. For example, the tag antenna may be a patch, a slot, a loop, a coil, a horn, a spiral, a monopole, microstrip, stripline, or any other suitable antenna.

Diagram 250 depicts top and side views of tag 252, formed using a strap. Tag 252 differs from tag 220 in that it includes a substantially planar strap substrate 254 having strap contacts 256 and 258. IC 224 is mounted on strap substrate 254 such that the IC contacts on IC 224 electrically couple to strap contacts 256 and 258 via suitable connections (not shown). Strap substrate 254 is then placed on inlay 222 such that strap contacts 256 and 258 electrically couple to antenna segments 226 and 228. Strap substrate 254 may be affixed to inlay 222 via pressing, an interface layer, one or more adhesives, or any other suitable means.

Diagram 260 depicts a side view of an alternative way to place strap substrate 254 onto inlay 222. Instead of strap substrate 254′s surface, including strap contacts 256/258, facing the surface of inlay 222, strap substrate 254 is placed with its strap contacts 256/258 facing away from the surface of inlay 222. Strap contacts 256/258 can then be either capacitively coupled to antenna segments 226/228 through strap substrate 254, or conductively coupled using a through-via which may be formed by crimping strap contacts 256/258 to antenna segments 226/228. In some examples, the positions of strap substrate 254 and inlay 222 may be reversed, with strap substrate 254 mounted beneath inlay 222 and strap contacts 256/258 electrically coupled to antenna segments 226/228 through inlay 222. Of course, in yet other examples strap contacts 256/258 may electrically couple to antenna segments 226/228 through both inlay 222 and strap substrate 254.

In operation, the antenna couples with RF signals in the environment and propagates the signals to IC 224, which may both harvest power and respond if appropriate, based on the incoming signals and the IC's internal state. If IC 224 uses backscatter modulation then it may generate a response signal (e.g., signal 126) from an RF signal in the environment (e.g., signal 112) by modulating the antenna's reflectance. Electrically coupling and uncoupling the IC contacts of IC 224 can modulate the antenna's reflectance, as can varying the admittance or impedance of a shunt-connected or series-connected circuit element which is coupled to the IC contacts. If IC 224 is capable of transmitting signals (e.g., has its own power source, is coupled to an external power source, and/or can harvest sufficient power to transmit signals), then IC 224 may respond by transmitting response signal 126. In the examples of FIG. 2, antenna segments 226 and 228 are separate from IC 224. In other examples, the antenna segments may alternatively be formed on IC 224.

An RFID tag such as tag 220 is often attached to or associated with an individual item or the item packaging. An RFID tag may be fabricated and then attached to the item or packaging, may be partly fabricated before attachment to the item or packaging and then completely fabricated upon attachment to the item or packaging, or the manufacturing process of the item or packaging may include the fabrication of the RFID tag. In some examples, the RFID tag may be integrated into the item or packaging. In this case, portions of the item or packaging may serve as tag components. For example, conductive item or packaging portions may serve as tag antenna segments or contacts. Nonconductive item or packaging portions may serve as tag substrates or inlays. If the item or packaging includes integrated circuits or other circuitry, some portion of the circuitry may be configured to operate as part or all of an RFID tag IC. Thus, an “RFID IC” need not be distinct from an item, but more generally refers to the item containing an RFID IC and antenna capable of interacting with RF waves and receiving and responding to RFID signals. Because the boundaries between IC, tag, and item are thus often blurred, the terms “RFID IC”, “RFID tag”, “tag”, or “tag IC” as used herein may refer to the IC, the tag, or even to the item as long as the referenced element is capable of RFID functionality.

The components of the RFID system of FIG. 1 may communicate with each other in any number of modes. One such mode is called full duplex, where both reader 110 and tag 120 can transmit at the same time. In some examples, RFID system 100 may be capable of full duplex communication. Another such mode, which may be more suitable for passive tags, is called half-duplex, and is described below.

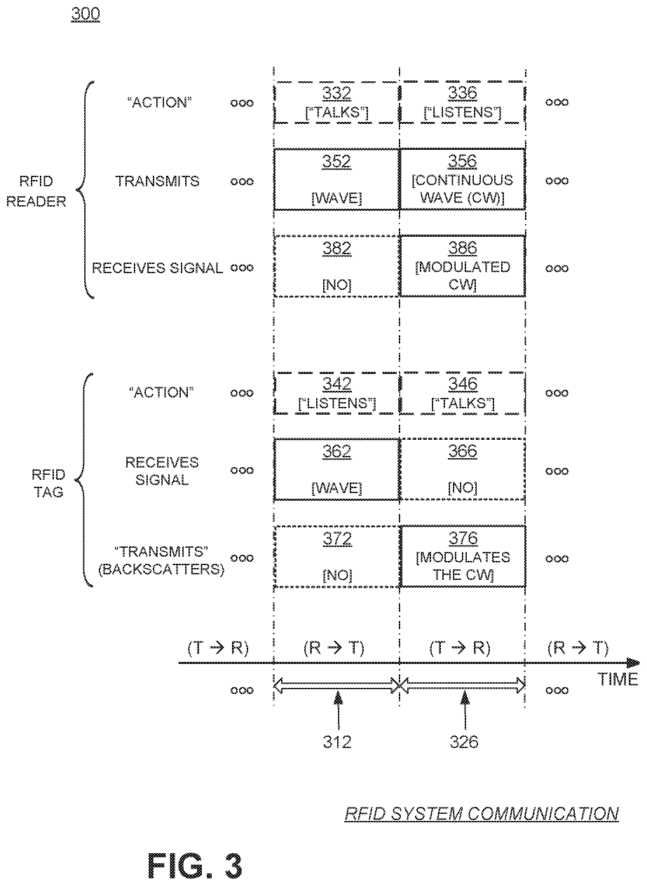

FIG. 3 is a conceptual diagram 300 for explaining half-duplex communications between the components of the RFID system of FIG. 1, in this case with tag 120 implemented as a passive tag. The explanation is made with reference to a TIME axis, and also to a human metaphor of “talking” and “listening”. The actual technical implementations for “talking” and “listening” are now described.

In a half-duplex communication mode, RFID reader 110 and RFID tag 120 talk and listen to each other by taking turns. As seen on axis TIME, reader 110 talks to tag 120 during intervals designated “R→T”, and tag 120 talks to reader 110 during intervals designated “T→R”. For example, a sample R→T interval occurs during time interval 312, during which reader 110 talks (block 332) and tag 120 listens (block 342). A following sample T→R interval occurs during time interval 326, during which reader 110 listens (block 336) and tag 120 talks (block 346). Interval 312 may be of a different duration than interval 326-here the durations are shown approximately equal only for purposes of illustration.

During interval 312, reader 110 transmits a signal such as signal 112 described in FIG. 1 (block 352), while tag 120 receives the reader signal (block 362), processes the reader signal to extract data, and harvests power from the reader signal. While receiving the reader signal, tag 120 does not backscatter (block 372), and therefore reader 110 does not receive a signal from tag 120 (block 382).

During interval 326, also known as a backscatter time interval or backscatter interval, reader 110 does not transmit a data-bearing signal. Instead, reader 110 transmits a continuous wave (CW) signal, which is a carrier that generally does not encode information. The CW signal provides energy for tag 120 to harvest as well as a waveform that tag 120 can modulate to form a backscatter response signal. Accordingly, during interval 326 tag 120 is not receiving a signal with encoded information (block 366) and instead modulates the CW signal (block 376) to generate a backscatter signal such as signal 126 described in FIG. 2. Tag 120 may modulate the CW signal to generate a backscatter signal by adjusting its antenna reflectance, as described above. Reader 110 then receives and processes the backscatter signal (block 386).

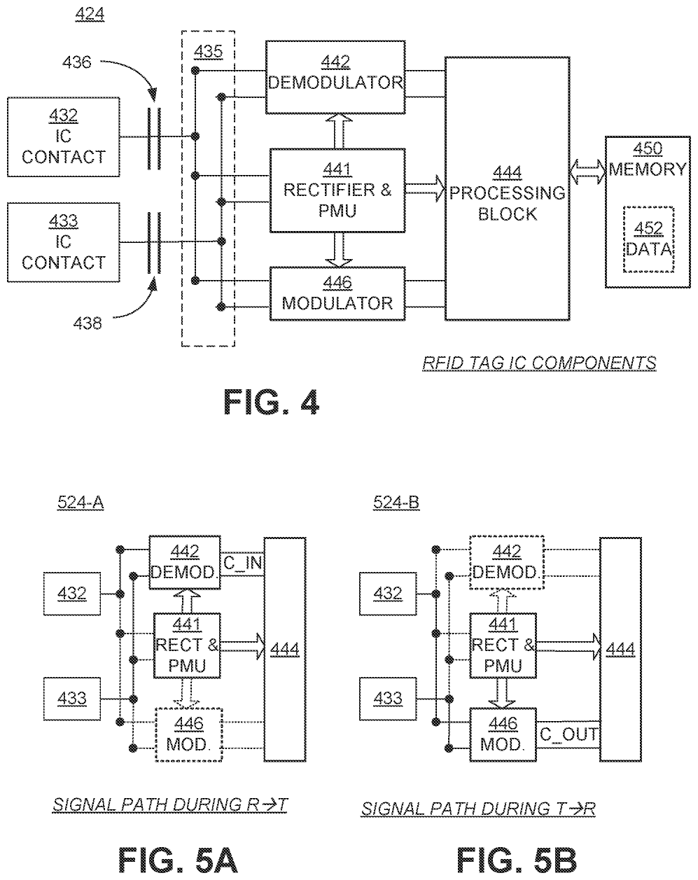

FIG. 4 is a block diagram showing a detail of an RFID IC, such as IC 224 in FIG. 2. Electrical circuit 424 may be implemented in an IC, such as IC 224. Circuit 424 implements at least two IC contacts 432 and 433, suitable for coupling to antenna segments such as antenna segments 226/228 in FIG. 2. When two IC contacts form the signal input from and signal return to an antenna they are often referred-to as an antenna port. IC contacts 432 and 433 may be made in any suitable way, such as from electrically conductive pads, bumps, or similar. In some examples circuit 424 implements more than two IC contacts, especially when configured with multiple antenna ports and/or to couple to multiple antennas.

Circuit 424 includes signal-routing section 435 which may include signal wiring, signal-routing busses, receive/transmit switches, and similar that can route signals between the components of circuit 424. IC contacts 432/433 may couple galvanically, capacitively, and/or inductively to signal-routing section 435. For example, optional capacitors 436 and/or 438 may capacitively couple IC contacts 432/433 to signal-routing section 435, thereby galvanically decoupling IC contacts 432/433 from signal-routing section 435 and other components of circuit 424.

Capacitive coupling (and the resultant galvanic decoupling) between IC contacts 432 and/or 433 and components of circuit 424 is desirable in certain situations. For example, in some RFID tag examples IC contacts 432 and 433 may galvanically connect to terminals of a tuning loop on the tag. In these examples, galvanically decoupling IC contact 432 from IC contact 433 may prevent the formation of a DC short circuit between the IC contacts through the tuning loop.

Capacitors 436/438 may be implemented within circuit 424 and/or partly or completely external to circuit 424. For example, a dielectric or insulating layer on the surface of the IC containing circuit 424 may serve as the dielectric in capacitor 436 and/or capacitor 438. As another example, a dielectric or insulating layer on the surface of a tag substrate (e.g., inlay 222 or strap substrate 254) may serve as the dielectric in capacitors 436/438. Metallic or conductive layers positioned on both sides of the dielectric layer (i.e., between the dielectric layer and the IC and between the dielectric layer and the tag substrate) may then serve as terminals of the capacitors 436/438. The conductive layers may include IC contacts (e.g., IC contacts 432/433), antenna segments (e.g., antenna segments 226/228), or any other suitable conductive layers.

Circuit 424 includes a rectifier and PMU (Power Management Unit) 441 that harvests energy from the RF signal incident on antenna segments 226/228 to power the circuits of IC 424 during either or both reader-to-tag (R→T) and tag-to-reader (T→R) intervals. Rectifier and PMU 441 may be implemented in any way known in the art, and may include one or more components configured to convert an alternating-current (AC) or time-varying signal into a direct-current (DC) or substantially time-invariant signal.

Circuit 424 also includes a demodulator 442, a processing block 444, a memory 450, and a modulator 446. Demodulator 442 demodulates the RF signal received via IC contacts 432/433, and may be implemented in any suitable way, for example using a slicer, an amplifier, and other similar components. Processing block 444 receives the output from demodulator 442, performs operations such as command decoding, memory interfacing, and other related operations, and may generate an output signal for transmission. Processing block 444 may be implemented in any suitable way, for example by combinations of one or more of a processor, memory, decoder, encoder, and other similar components. Memory 450 stores data 452, and may be at least partly implemented as permanent or semi-permanent memory such as nonvolatile memory (NVM), EEPROM, ROM, or other memory types configured to retain data 452 even when circuit 424 does not have power. Processing block 444 may be configured to read data from and/or write data to memory 450.

Modulator 446 generates a modulated signal from the output signal generated by processing block 444. In one embodiment, modulator 446 generates the modulated signal by driving the load presented by antenna segment(s) coupled to IC contacts 432/433 to form a backscatter signal as described above. In another embodiment, modulator 446 includes and/or uses a transmitter to generate and transmit the modulated signal via antenna segment(s) coupled to IC contacts 432/433. Modulator 446 may be implemented in any suitable way, for example using a switch, driver, amplifier, and other similar components. Demodulator 442 and modulator 446 may be separate components, combined in a single transceiver circuit, and/or part of processing block 444.

In some examples, particularly in those with more than one antenna port, circuit 424 may contain multiple demodulators, rectifiers, PMUs, modulators, processing blocks, and/or memories.

FIG. 5A shows version 524-A of components of circuit 424 of FIG. 4, further modified to emphasize a signal operation during a R→T interval (e.g., time interval 312 of FIG. 3). During the R→T interval, demodulator 442 demodulates an RF signal received from IC contacts 432/433. The demodulated signal is provided to processing block 444 as C_IN, which in some examples may include a received stream of symbols. Rectifier and PMU 441 may be active, for example harvesting power from an incident RF waveform and providing power to demodulator 442, processing block 444, and other circuit components. During the R→T interval, modulator 446 is not actively modulating a signal, and in fact may be decoupled from the RF signal. For example, signal routing section 435 may be configured to decouple modulator 446 from the RF signal, or an impedance of modulator 446 may be adjusted to decouple it from the RF signal.

FIG. 5B shows version 524-B of components of circuit 424 of FIG. 4, further modified to emphasize a signal operation during a T→R interval (e.g., time interval 326 of FIG. 3). During the T→R interval, processing block 444 outputs a signal C_OUT, which may include a stream of symbols for transmission. Modulator 446 then generates a modulated signal from C_OUT and sends the modulated signal via antenna segment(s) coupled to IC contacts 432/433, as described above. During the T→R interval, rectifier and PMU 441 may be active, while demodulator 442 may not be actively demodulating a signal. In some examples, demodulator 442 may be decoupled from the RF signal during the T→R interval. For example, signal routing section 435 may be configured to decouple demodulator 442 from the RF signal, or an impedance of demodulator 442 may be adjusted to decouple it from the RF signal.

In typical examples, demodulator 442 and modulator 446 are operable to demodulate and modulate signals according to a protocol, such as the Gen2 Protocol mentioned above. In examples where circuit 424 includes multiple demodulators modulators, and/or processing blocks, each may be configured to support different protocols or different sets of protocols. A protocol specifies, in part, symbol encodings, and may include a set of modulations, rates, timings, or any other parameter associated with data communications. A protocol can be a variant of an internationally ratified protocol such as the Gen2 Protocol, for example including fewer or additional commands than the ratified protocol calls for, and so on. In some instances, additional commands may sometimes be called custom commands.

Integrated circuits for use in RFID tags tend to be very small. For example, some RFID ICs are less than half a millimeter in length and width. To ease assembly of such tiny ICs onto tag substrates or inlays to form RFID tags, some of these ICs may include large (relative to the IC size) contact pads, to facilitate alignment of the ICs to antenna terminals on the tag substrates or inlays.

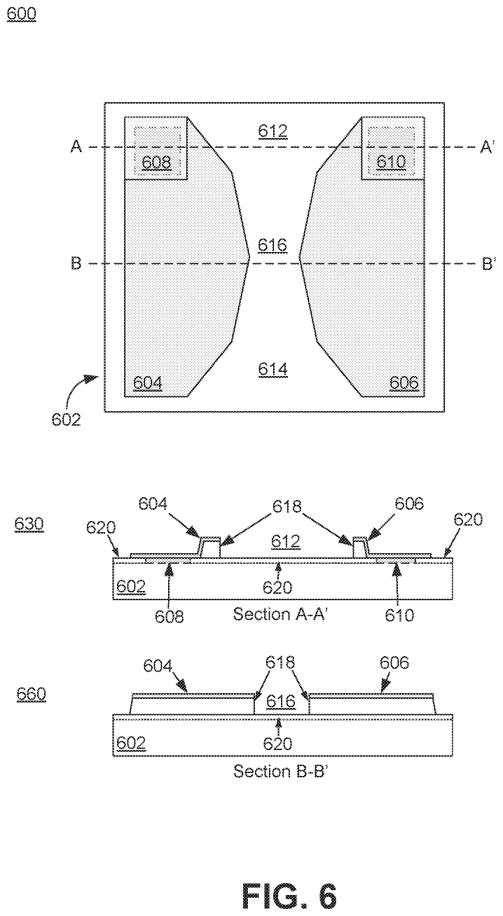

One example of an IC with large contact pads is IC 602 depicted in FIG. 6, in top-down diagram 600, cutaway view 630 along section A-A′, and cutaway view 660 along section B-B′. IC 602 has two large contact pads 604 and 606, electrically coupled to IC contacts 608 and 610, respectively. IC contacts 608 and 610 in turn electrically couple to circuitry within IC 602. Large contact pads 604 and 606 are formed of an electrically conductive material, such as a metal or similar, and are disposed on portions of a repassivation layer 618, shown in views 630 and 660. The repassivation layer 618 is a relatively thick layer of one or more electrically insulating organic materials, such as polyimide. Repassivation layer 618 helps to (a) even out mounting forces across the IC 602 during assembly onto a tag inlay and (b) reduce undesirable coupling (e.g., capacitive or inductive) between large contact pads 604 and 606 and circuitry in the IC 602, for example as described in commonly assigned U.S. Pat. No. 8,511,569, issued on Aug. 20, 2013, hereby incorporated by reference in its entirety. Repassivation layer 618 is disposed on an insulating layer 620 of the IC 602. The insulating layer 620 may be an oxide or nitride layer and can be deposited on IC 602 as part of fabrication, for example to protect underlying interconnect structures.

During assembly of an RFID IC such as IC 602 onto a tag inlay, contact structures such as pads (e.g., pads 604/606) or bumps on the IC are electrically coupled to antenna terminals on the tag inlay such that circuitry within the IC is electrically coupled to one or more antennas on the tag inlay. The size of large contact pads 604 and 606 makes it easier to appropriately position those contact pads with respect to the antenna terminals on the tag inlay as compared to an RFID IC with smaller contact pads or even contact bumps, as described in commonly assigned U.S. Pat. No. 9,633,302, issued on Apr. 25, 2017, hereby incorporated by reference in its entirety.

As mentioned above, RFID ICs can be tiny, on the order of hundreds of micrometers on a side or even smaller. When these ICs are fabricated on semiconductor wafers, using die-separation or dicing techniques such as physical sawing or stealth dicing may (a) significantly impact die-per-wafer yields because of their requirements for relatively large scribe lanes, and (b) significantly increase dicing time due to the combination of their inherently serial natures with the large number of dies on the wafer. To address the latter, a dicing technique using a dry etch process (also known as a plasma etch process) to simultaneously etch all of the scribe lanes can be used. Proper configuration of the dry etching process can also reduce the required scribe lane width, which addresses the former concern.

One such dry etching process is deep reactive ion etching, or DRIE. DRIE combines a highly directional physical/chemical etch step (using a plasma) with a subsequent sidewall protection step involving the deposition of protective material. These two steps, when repeated, allow the formation of high-aspect-ratio holes or trenches.

In some situations, the protective material deposited during the sidewall protection step of the etching process can cause issues with subsequent/downstream processing. For example, if the protective material is a fluoropolymer, the fluoropolymer may also be deposited on other portions of the ICs during the etching process. When these ICs are later assembled onto tag inlays, the presence of the fluoropolymer can prevent adhesives from properly adhering to the ICs, leading to failed tag assembly or to assembled tags with lower-than-desired die-to-inlay shear strength. Unfortunately, in some situations deposited fluoropolymers may be difficult to remove, especially from metals (e.g., on IC contact pads) and organic dielectrics (e.g., a repassivation layer such as repassivation layer 618).

In some examples, ICs can be fabricated to both have relatively large contact pads and be less susceptible to the fluoropolymer problem described above. For example, using IC 602 as a reference, portions of IC 602 that are not covered by large contact pads 604 and 606 can be stripped down to expose the insulating layer 620 beneath the repassivation layer 618. Fluoropolymer deposited on oxide or nitride insulating layers may be easier to remove than fluoropolymer on metal or organic dielectric layers. Accordingly, fluoropolymer deposited on those stripped-down portions of IC 602 with exposed portions of insulating layer 620 can be relatively easily removed, resulting in improved adhesive adhesion to those cleaned portions. For IC 602, the relatively wide, opposing portions 612 and 614 located near the north side and south side of the IC (where in FIG. 6 and other figures herein “north” corresponds to “toward the top of the figure”, “south” to “toward the bottom of the figure”, etc.), combined with the inter-pad channel 616 connecting 612 and 614, can be cleaned of fluoropolymer (e.g., by using an oxygen plasma) to provide area for adhesives to adhere and fasten IC 602 to a tag substrate or inlay. In some examples, the portions 612, 614, and/or channel 616 may be referred to as “anchor regions”, specific areas prepared to allow adhesives to adhere well (e.g., by oxygen plasma cleaning). In some examples, the periphery of IC 602, around pads 604 and 606, may also provide some area for adhesives.

Stripping portions of an IC (e.g., IC 602) down to an insulating layer can be done by removing portions of repassivation layer (e.g., layer 618) on those IC portions. Such removal can be done using wet or dry etching, or any other suitable means. Removal of repassivation layer portions may occur in a specific process step, or may be part of another process step, such as during removal of a different masking layer.

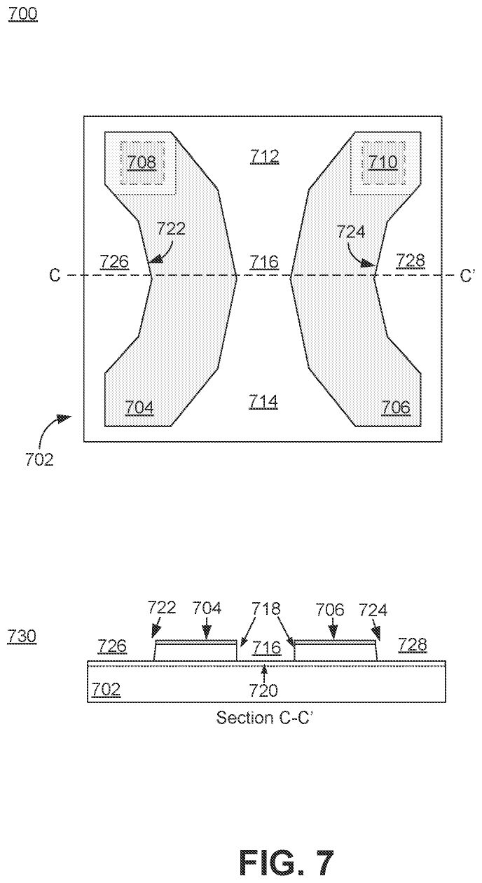

In some cases, the anchor regions on IC 602 may not provide sufficient area for adequate adhesion to a tag substrate or inlay. In these cases, an IC may be designed to expose insulating layer portions in additional areas, so that overall adhesion of the IC to a tag substrate or inlay is stronger. In one embodiment, an IC can be designed to have large contact pad patterns with cutouts to provide additional areas for adhesion. FIG. 7 depicts such an IC 702, shown in top-down diagram 700 and cutaway view 730 along section C-C′. IC 702 is similar to IC 602, except that large contact pads 704 and 706 have cutouts 722 and 724, on the west (corresponding to “toward the left of the figure”) side and east (corresponding to “toward the right of the figure”) side of IC 702, respectively. Cutouts 722 and 724 expose areas 726 and 728, respectively of an insulating layer 720. These areas 726 and 728, upon suitable preparation, can provide adhesion in addition to portions 712, 714, and channel 716 (similar to portions 612, 614, and channel 616). This provides four anchor regions on the north, south, west, and east sides of IC 702, as well as a fifth anchor region for adhesion near the center of IC 702 (channel 716). Such four (plus) point attachment provides stronger adhesion to a tag substrate or inlay than the two (plus) point attachment possible with IC 602.

Other configurations of large contact pads and cutouts are possible. For example, in one embodiment cutouts or anchor regions may be disposed at or near the corners of the IC. In another embodiment, cutouts such as cutouts 722 and 724 may be connected by another channel, orthogonal to channel 716. This would result in large contact pads 704 and 706 each being divided into two portions.

While cutouts 722 and 724 are shown as similar and symmetric, cutouts do not have to be similar and/or symmetric. In fact, cutouts in large contact pads that expose areas providing adhesion may be of any suitable shape and size, as long as the large contact pads can make adequate electrical contact to antenna leads or terminals on a tag substrate/inlay. These cutouts and their lack of repassivation layer may reduce some of the benefits provided by the repassivation layer (e.g., evening out mounting forces and/or reducing undesirable electrical coupling), but these tradeoffs may be worthwhile for improved adhesion.

The top surfaces of ICs 602 and 702 are depicted as lacking repassivation layer portions in all areas not otherwise covered by large contact pads 604, 606, 704, and 706. In other examples, at least some areas of an IC top surface may be covered by repassivation layer portions but not by a large contact pad, as long as repassivation layer portions are not present in the desired anchor regions.

Recall, as mentioned above, that one of the purposes of having a repassivation layer is to enforce a physical separation between an IC's large contact pads and circuitry within the IC to reduce undesirable coupling. The repassivation layer also enforces a physical separation between circuitry within the IC and conductive antenna terminals or leads on a tag inlay, thereby reducing undesirable coupling between the IC and the tag inlay antenna terminals or leads. When ICs such as ICs 602 and 702 that have repassivation layers under contact pads but not within the inter-pad channels are assembled onto tag inlays, the gap in the inter-pad channels due to the lack of repassivation layer there may allow tag inlays to mechanically deform and intrude into the channel and approach the surface of the insulation layer. If those tag inlay portions that intrude into the channel include conductive antenna terminal or lead portions, then undesirable coupling between those conductive antenna terminal or lead portions and circuitry within the IC may occur, partially defeating the purpose of having a repassivation layer.

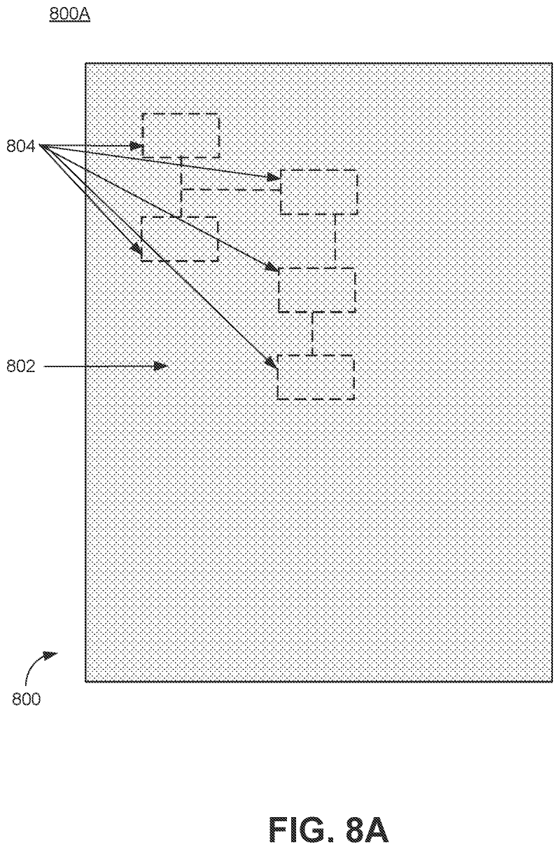

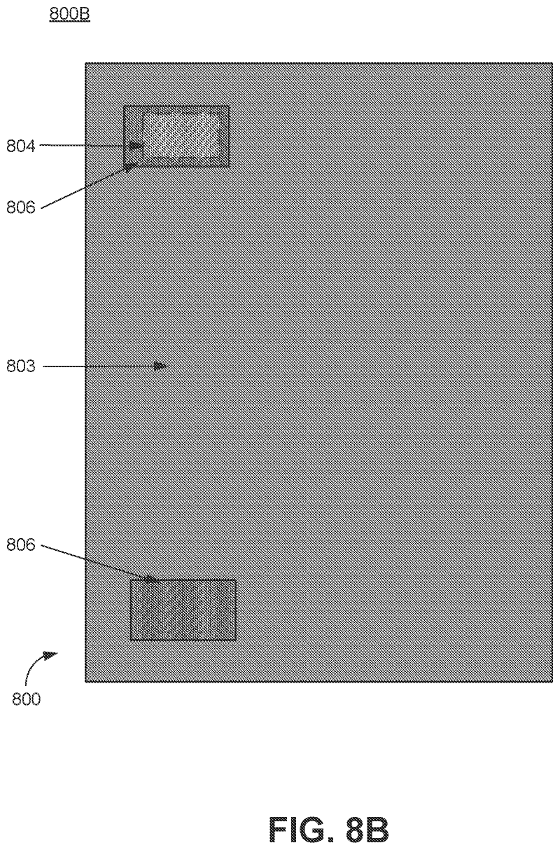

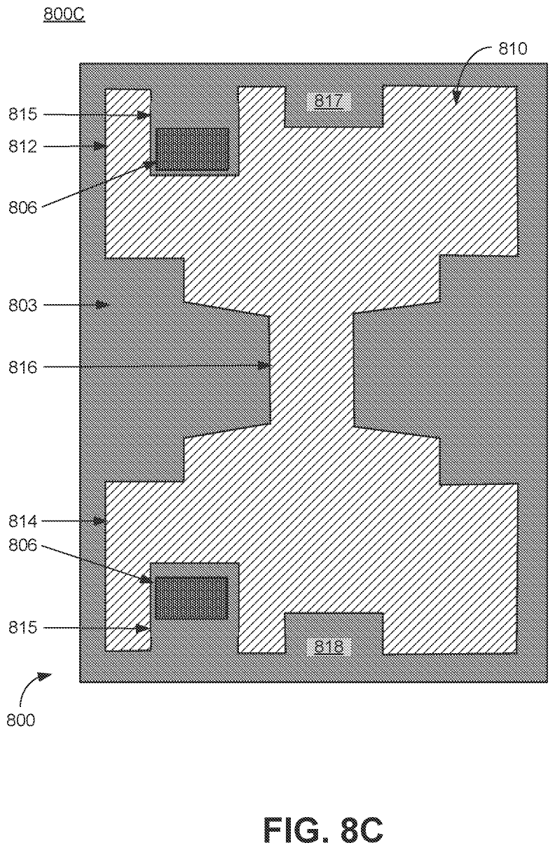

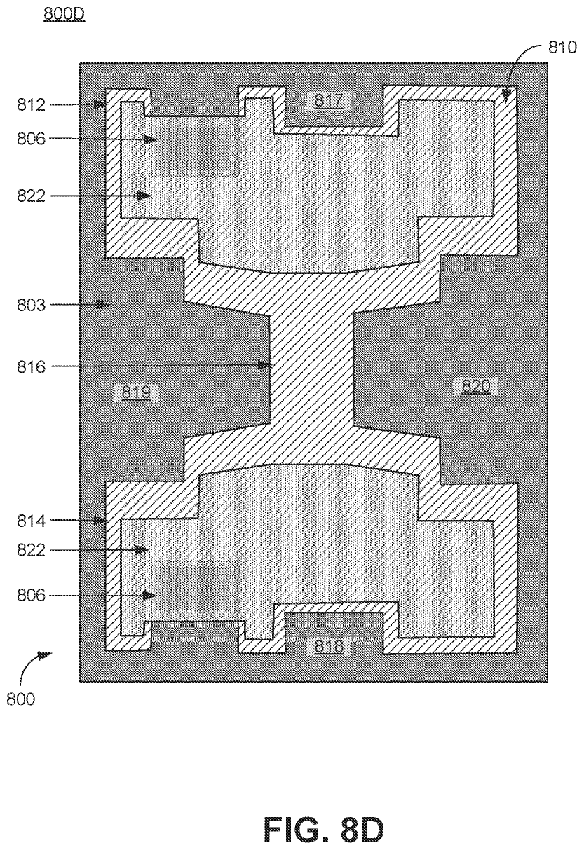

FIGS. 8A through 8D illustrate various layers of an RFID IC 800 with a support structure configured to address this issue. Diagram 800A in FIG. 8A shows a semiconductor substrate 802 of the RFID IC 800 with embedded circuitry 804. The circuitry 804 may be fabricated as described above in relation to FIG. 2, and may include circuit components as described above in relation to FIG. 4.

Diagram 800B shows substrate 802 with an insulating layer 803 and IC contacts 806. The insulating layer 803 covers the substrate 802 as well as the embedded circuitry 804. The IC contacts 806, which are metallic or otherwise electrically conductive, are either disposed on top of insulating layer 803 or in the same layer as insulating layer 803 (for example, within cutouts of insulating layer 803). The IC contacts 806 are electrically coupled to circuitry 804 galvanically or capacitively. For example, if the IC contacts 806 are disposed on top of insulating layer 803, the IC contacts 806 may couple to circuitry 804 galvanically through a via passing through the insulating layer 803 or capacitively through the insulating layer 803 itself. If the IC contacts 806 are in the same layer as insulating layer 803, then the IC contacts 806 may couple to circuitry 804 galvanically through an interconnect structure or capacitively through one or more coupling capacitors. The insulating layer 803 may be formed on the substrate 802 as part of wafer fabrication, for example to protect underlying interconnect structures. In some examples, the insulating layer 803 may be an oxide layer formed through oxidization of the top surface of the substrate 802. The insulating layer 803 may also be a nitride layer.

Diagram 800C in FIG. 8C shows a repassivation layer 810, similar to repassivation layer 618 described above, formed over the insulating layer 803. The repassivation layer 810 may include three main portions: two large portions 812 and 814 and a narrower (relative to large portions 812/814) neck portion 816 coupling the two large portions 812 and 814 such that the repassivation layer 810 has an hourglass shape. Similar to repassivation layer 618, the repassivation layer 810 is a relatively thick layer of one or more electrically insulating organic materials, such as polyimide, that (a) assisting in evening out mounting forces across IC 800 during assembly onto a tag inlay and (b) may also reduce undesirable coupling (e.g., capacitive or inductive) between conductive structures such as large contact pads and the circuitry in the IC 800.

The repassivation layer 810 may be configured or shaped to expose certain portions of insulating layer 803 and/or IC contacts 806. For example, notches 815 in the repassivation layer 810 expose the IC contacts 806 for subsequent electrical coupling, while notches 817 and 818 expose portions of insulating layer 803 suitable for anchor regions. The shape of the repassivation layer 810 may be determined based on manufacturing techniques (e.g., type of etching), materials, and sizes of the IC contacts or desired exposed portions of insulating layer 803. In some examples, instead of notches, openings within the repassivation layer 810 may be formed to expose IC contacts or insulating layer portions.

Diagram 800D in FIG. 8D shows contact pads 822 formed on the large portions 812 and 814 of the repassivation layer 810. The contact pads 822 may be electrically coupled to the IC contacts 806 through galvanic, capacitive, or inductive coupling. During assembly of the RFID IC 800 to a tag inlay, the contact pads 822 are configured to electrically couple to antenna terminals or leads on the tag inlay, thereby electrically coupling the circuitry 804 of the IC to the tag inlay antenna terminals/leads, and eventually to one or more antennas on the tag inlay or elsewhere. While the example configurations in diagrams 800A-800D are shown with two contact pads (for a two-terminal antenna connection), other configurations may also be implemented. For example, an IC configured to couple to dual antennas may include four contact pads.

In diagram 800D, the neck portion 816 serves as at least part of a support structure configured to enforce a physical separation between circuitry 804 (within the IC) and an attached tag inlay. The support structure and neck portion 816 enforce the physical separation by supporting or holding up the tag inlay at and near its location, thereby reducing the extent to which the tag inlay mechanically deforms. The support structure may be centered at or near the center of the IC 800, and the neck portion 816 of the support structure separates two anchor regions 819 and 820. While in diagram 800D the width of the neck portion 816 is relatively narrow with respect to the width of IC 800, where width is measured from “west” to “east” (as defined above), in other examples the neck portion could be wider. In some examples, the combined area of anchor regions 819 and 820 may be between about 10% and about 90% of the total area of IC 800 between the contact pads 822. The support structure, and in this embodiment the neck portion 816, may have a height, width, length, and/or arrangement (for multi-part support structures—see below) selected to mitigate deformation of a tag inlay structure during mounting of the IC to the tag inlay structure. For example, the dimensions or arrangement of the support structure may be selected to mitigate the deformation of the inlay by limiting the deformation to less than 10%, 20%, or 30% of the spacing between an undeformed inlay and the surface of insulating layer 803. The dimensions (e.g., height) and/or arrangement may also be selected sufficiently to mitigate a deformation of the inlay such that a potential mounting capacitance variation of the assembled IC-inlay combination is less than 10% (or 1-sigma). In some examples, the maximum height (measured from the surface of insulating layer 803) of the support structure or the neck portion 816 may be anywhere between 50% to 100% of the height of the top surface of contact pads 822, inclusive.

The support structure may also serve to mitigate misalignment during assembly of IC 800 to a tag inlay. As described in previously referenced U.S. Pat. No. 9,633,302, turbulence from adhesive fluid flow during IC-inlay attachment may cause misalignment. In some situations, the presence and movement of bubbles in the adhesive may contribute to turbulence and misalignment. In these situations, the support structure can mitigate the misaligning effect due to adhesive bubbles. Specifically, the support structure, being a discrete layer raised from the surface of insulating layer 803, has step edges at its “western” and “eastern” edges. These step edges may disrupt adhesive bubble formation and/or cause large adhesive bubbles to break into smaller bubbles, thereby reducing bubble-induced turbulence and misalignment.

While in diagram 800D the support structure includes neck portion 816 connecting large portions 812 and 814 of repassivation layer 810, other types of support structure implementations can be used. One example support structure may include a neck portion that has one or more at least partial discontinuities, creating one or more small channels between and potentially connecting anchor regions 819 and 820. These small channel(s) may have depths that varies between 5% to 100% (of the height of the support structure/neck portion), inclusive. Another example support structure may include one or more standalone (i.e., not connecting large portions 812 and 814) pillars or similar elevated structures disposed between anchor regions 819 and 820. In this example, there is a channel connecting anchor regions 819 and 820, and the support structure is located within the channel. At least a portion of the support structure may be located at a midpoint of the channel between anchor regions 819 and 820, while other support structure portions may be located elsewhere in the channel.

In other examples, the IC may include a channel between the first and second contact pads, where the first anchor region is at a first end of the channel, the second anchor region is at a second end of the channel, opposite the first end, and at least a portion of the support structure is at a midpoint of the channel between the first and second ends.

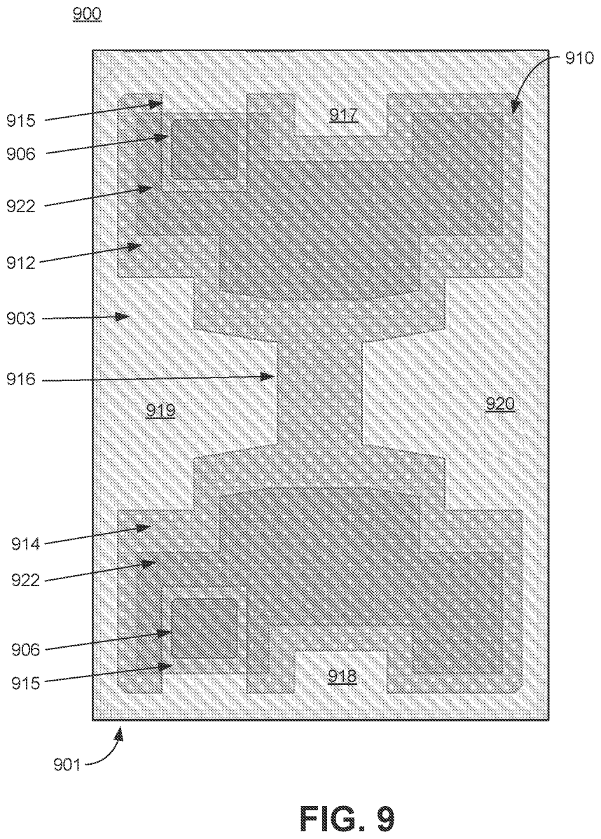

FIG. 9 illustrates a see-through top view of an RFID IC 901 with a support structure. Diagram 900 shows an RFID IC 901 with a top surface of the substrate covered by insulating (oxide or nitride) layer 903. An hourglass-shaped repassivation layer 910 with first and second portions 912 and 914, and a neck portion 916 connecting the portions 912 and 914 may be disposed on the insulating layer 903. Parts of the repassivation layer 910 such as notches 915, 917, and 918 may expose IC contacts 906 and portions of insulating layer 903. The IC contacts 906 may be electrically coupled to contact pads 922 disposed on the first and second portions 912, 914 of the repassivation layer.

In some examples, at least the anchor regions 919 and 920 on either side of the neck portion 916 may be used to place an adhesive on for adhering the IC 901 to a tag inlay, while the support structure (neck portion 916) may be used to mitigate a deformation of the inlay as well as mitigate misalignment during mounting of the IC 901 to the tag inlay.

In some examples, an RFID integrated circuit (IC), may include a semiconductor substrate including circuitry; an insulating layer on the semiconductor substrate; first and second openings in the insulating layer uncovering first and second IC contacts, the IC contacts electrically coupled to the circuitry; a first contact pad electrically coupled to the first IC contact; a second contact pad electrically coupled to the second IC contact; a support structure disposed on the insulating layer and between the first and second contact pads, the support structure configured to mitigate a deformation of an inlay during mounting of the IC to the inlay; a first portion of the insulating layer exposed between the first and second contact pads; and a second portion of the insulating layer exposed between the first and second contact pads, where the first portion and the second portion of the insulating layer are exposed to adhere to an adhesive for bonding the IC to the inlay, and the support structure is disposed between the first and second portions of the insulating layer.

In other examples, the RFID IC may further include a repassivation layer disposed on the insulating layer, where the first contact pad is disposed on a first portion of the repassivation layer; and the second contact pad is disposed on a second portion of the repassivation layer. The support structure may include at least a third portion of the repassivation layer. The support structure may physically connect the first and second contact pads. The support structure, the first contact pad, and the second contact pad may form an hourglass shape in which the support structure forms a neck of the hourglass shape separating a first anchor region from a second anchor region. The RFID IC may further include a channel between the first and second contact pads, where the first anchor region is at a first end of the channel, the second anchor region is at a second end of the channel, opposite the first end, and at least a portion of the support structure is at a midpoint of the channel between the first and second ends. A combination of the first and second portions of the insulating layer may have an area between 10% and 90% of a portion of the insulating layer between the first and second contact pads. A height of the support structure may be selected sufficiently to mitigate the deformation of the inlay by limiting the deformation to less than 10% of a spacing between a surface of the insulating layer and the undeformed inlay. A height of the support structure may be selected sufficiently to mitigate a deformation of the inlay such that a potential mounting capacitance variation an assembled combination of the IC and the inlay is less than 10%.

In further examples, an RFID integrated circuit (IC) may include a semiconductor substrate; an insulating layer disposed on the semiconductor substrate; a first contact pad disposed on the insulating layer; a second contact pad disposed on the insulating layer; a support structure disposed on the insulating layer, the support structure configured to separate the insulating layer from an inlay when the IC is bonded to the inlay; a first portion of the insulating layer exposed between the first and second contact pads; and a second portion of the insulating layer exposed between the first and second contact pads, where the first portion and the second portion of the insulating layer are exposed to adhere to an adhesive for bonding the IC to the inlay, and the support structure is disposed between the first and second contact pads and between the first and second exposed insulating layer portions.

In yet other examples, the RFID IC may further include a repassivation layer disposed on the insulating layer, where the first contact pad is disposed on a first portion of the repassivation layer; and the second contact pad is disposed on a second portion of the repassivation layer. The support structure may include at least a third portion of the repassivation layer. The support structure may physically connect the first and second contact pads. A combination of the first and second portions of the insulating layer may have an area between 10% and 90% of a portion of the insulating layer between the first and second contact pads.

In some examples, an RFID integrated circuit (IC) may include a semiconductor substrate including circuitry; a first IC contact and a second IC contact on a surface of the semiconductor substrate and electrically coupled to the circuitry; an insulating layer on the surface of the semiconductor substrate that exposes the first and second IC contacts; an hourglass-shaped repassivation structure disposed on the insulating layer and comprising a first section, a second section, and a neck connecting the first and second sections and separating a first anchor region from a second anchor region; a first contact pad disposed on the first section of the repassivation structure and electrically coupled to the first IC contact; a second contact pad disposed on the second section of the repassivation structure and electrically coupled to the second IC contact, where the neck has a height selected sufficiently to mitigate deformation of an inlay structure during mounting of the IC to the inlay structure, the first anchor region exposes a first portion of the insulating layer to adhere to an adhesive for bonding the IC to the inlay structure, and the second anchor region exposes a second portion of the insulating layer to adhere to the adhesive for bonding the IC to the inlay structure.

In other examples, the RFID IC may further include a channel between the first and second contact pads, where the first anchor region is at a first end of the channel, the second anchor region is at a second end of the channel, opposite the first end, and at least a portion of the repassivation structure is at a midpoint of the channel between the first and second ends. The height of the repassivation structure may be selected sufficiently to mitigate the deformation of the inlay such that a potential mounting capacitance variation between the IC and the inlay structure is less than 10%. The repassivation structure may physically connect the first and second contact pads.

The present disclosure is not to be limited in terms of the particular examples described in this application, which are intended as illustrations of various aspects. Many modifications and variations can be made without departing from its spirit and scope. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, configurations, tags, RFICs, readers, systems, and the like, which can, of course, vary. It is also to be understood that the terminology used herein is for the purpose of describing particular examples only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

In general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). If a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, such recitation should be interpreted to mean at least the recited number (e.g., the bare recitation of “two recitations,” without other modifiers, means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). Any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

For any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. All language such as “up to,” “at least,” “greater than,” “less than,” and the like include the number recited and refer to ranges which can be subsequently broken down into subranges as discussed above. Finally, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

1. A radio frequency identification (RFID) integrated circuit (IC), comprising:
a semiconductor substrate;
an insulating layer disposed on the semiconductor substrate;
a first contact pad disposed on the insulating layer;
a second contact pad disposed on the insulating layer;
a support structure disposed on the insulating layer, the support structure configured to separate the insulating layer from an inlay when the IC is bonded to the inlay;
a first portion of the insulating layer exposed between the first and second contact pads; and
a second portion of the insulating layer exposed between the first and second contact pads, wherein:
the first portion and the second portion of the insulating layer are exposed to adhere to an adhesive for bonding the IC to the inlay, and
the support structure is disposed between the first and second contact pads and between the first and second exposed insulating layer portions.

2. The RFID IC of claim 1, wherein the support structure is further configured to, during mounting of the IC to the inlay, at least one of:
support the inlay to mitigate a deformation of the inlay; and
reduce turbulence to mitigate misalignment.

3. The RFID IC of claim 1, further comprising a repassivation layer disposed on the insulating layer, wherein:
the first contact pad is disposed on a first portion of the repassivation layer;
the second contact pad is disposed on a second portion of the repassivation layer; and
the support structure includes at least a third portion of the repassivation layer.

4. (canceled)

5. The RFID IC of claim 3, wherein the third portion of the repassivation layer physically connects the first and second portions of the repassivation layer.

6. (canceled)

7. The RFID IC of claim 3, further comprising a channel between the first and second contact pads, wherein the first exposed insulating layer portion is at a first end of the channel, the second exposed insulating layer portion is at a second end of the channel, opposite the first end, and at least a portion of the support structure is at a midpoint of the channel between the first and second ends.

8. The RFID IC of claim 1, wherein a combination of the first and second portions of the insulating layer has an area between 10% and 90% of a portion of the insulating layer between the first and second contact pads.

9. The RFID IC of claim 1, wherein a height of the support structure is selected sufficiently to mitigate the deformation of the inlay by limiting the deformation to less than 10% of a spacing between a surface of the insulating layer and the undeformed inlay.

10. The RFID IC of claim 1, wherein a height of the support structure is selected sufficiently to mitigate a deformation of the inlay such that a potential mounting capacitance variation of an assembled combination of the IC and the inlay is less than 10%.

11. A radio frequency identification (RFID) integrated circuit (IC), comprising:
a semiconductor substrate including circuitry;
a first IC contact and a second IC contact on a surface of the semiconductor substrate and electrically coupled to the circuitry;
an insulating layer on the surface of the semiconductor substrate that uncovers the first IC contact through a first opening and uncovers the second IC contact through a second opening;
an hourglass-shaped repassivation structure disposed on the insulating layer;
a first contact pad disposed on the repassivation structure and electrically coupled to the first IC contact; and
a second contact pad disposed on the repassivation structure and electrically coupled to the second IC contact.

12. The RFID IC of claim 11, wherein the hourglass-shaped repassivation structure includes a first section, a second section, and a neck connecting the first and second sections.

13. The RFID IC of claim 12, wherein:
the first contact pad is disposed on the first section; and
the second contact pad is disposed on the second section.

14. The RFID IC of claim 12, further comprising:
a first exposed portion of the insulating layer between the first and second sections and on a first side of the neck, configured to adhere to an adhesive for bonding the IC to an inlay structure; and
a second exposed portion of the insulating layer between the first and second sections and on a second side of the neck opposite the first side, configured to adhere to the adhesive for bonding the IC to the inlay structure.

15. The RFID IC of claim 14, wherein
a combination of the first and second portions of the insulating layer has an area between 10% and 90% of a portion of the insulating layer between the first and second sections.

16. The RFID IC of claim 12, wherein the neck has a height selected sufficiently to mitigate deformation of an inlay structure during mounting of the IC to the inlay structure.

17. The RFID IC of claim 16, wherein the height of the neck is selected sufficiently to mitigate the deformation of the inlay by limiting the deformation to less than 10% of a spacing between a surface of the insulating layer and the undeformed inlay.

18. The RFID IC of claim 16, wherein the height of the neck is selected sufficiently to mitigate a deformation of the inlay such that a potential mounting capacitance variation an assembled combination of the IC and the inlay is less than 10%.

19. A method to form a radio frequency identification (RFID) integrated circuit (IC), comprising:
providing a semiconductor substrate including circuitry, an insulating layer, and first and second IC contacts, wherein the first and second IC contacts electrically couple to the circuitry and the insulating layer uncovers the first and second IC contacts;
forming a first contact structure raised from the insulating layer and including a first contact pad electrically coupled to the first IC contact;
forming a second contact structure raised from the insulating layer and including a second contact pad electrically coupled to the second IC contact;
forming a support structure disposed between the first and second contact structures and raised sufficiently from the insulating layer to mitigate deformation of an inlay structure during mounting of the IC to the inlay structure;
exposing a first portion of the insulating layer adjacent to the support structure and between the first and second contact structures to receive an adhesive for adhering to the inlay structure; and
exposing a second portion of the insulating layer adjacent to the support structure, opposite the first insulating layer portion, and between the first and second contact structures to receive the adhesive for adhering to the inlay structure.

20. The method of claim 19, further comprising:
depositing first, second, and third repassivation layer portions on the insulating layer;
forming the first contact structure by forming at least part of the first contact pad on the first repassivation layer portion;
forming the second contact structure by forming at least part of the second contact pad on the second repassivation layer portion; and
forming at least part of the support structure from the third repassivation layer portion.

21. The method of claim 20, further comprising depositing the first, second, and third repassivation layer portions to create an hourglass shape in which the support structure forms a neck of the hourglass shape and separates the first insulating layer portion from the second insulating layer portion.

22. The method of claim 20, further comprising depositing the first, second, and third repassivation layer portions to create a channel between the first and second contact structures, wherein the first insulating layer portion is at a first end of the channel, the second insulating layer portion is at a second end of the channel opposite the first channel end, and at least a portion of the support structure is at a midpoint of the channel between the first and second channel ends.
